(19) United States
(12) Patent Application Publication
(10) Pub. No.: US 2026/0367184 A1
(43) Pub. Date: Nov. 19, 2026

(54) SYSTEM AND METHOD FOR MONITORING STATE OF POWER ELECTRONIC DEVICE USING ELECTROMAGNETIC VOICEPRINT

(71) Applicant: TSINGHUA UNIVERSITY, Beijing (CN)

(72) Inventors: Songling HUANG, Beijing (CN); Shuzhi WEN, Beijing (CN); Lisha PENG, Beijing (CN); Bingkun WEI, Beijing (CN); Shisong LI, Beijing (CN)

(21) Appl. No.: 19/371,024

(22) Filed: Oct. 28, 2025

(30) Foreign Application Priority Data
Oct. 28, 2024 (CN) 202411506667.9

(51) Int. Cl. G01R 31/56; G01R 29/08; G01R 31/00

(52) U.S. Cl. CPC G01R 31/56; G01R 29/0878; G01R 29/0892; G01R 31/001

(57) ABSTRACT

The present disclosure provides a system and a method for monitoring a state of a power electronic device using an electromagnetic voiceprint. The system includes an electromagnetic voiceprint acquisition apparatus and a system main control module. The electromagnetic voiceprint acquisition apparatus includes a resonant piezoelectric velocity sensor, a voiceprint signal collection module, a self-powered-taking power supply module and a first wireless communication module. The system main control module includes a second wireless communication module, a central processor, a voiceprint storage unit, a voiceprint display unit and an aging assessment module. The second wireless communication module is in communication connection with the first wireless communication module.

### CROSS-REFERENCE TO RELATED APPLICATIONS

This application claims priority to Chinese Patent Application No. 202411506667.9, filed on Oct. 28, 2024, the entire disclosure of which is hereby incorporated herein by reference.

### TECHNICAL FIELD

The present disclosure relates to the field of aging monitoring of a power electronic device, and in particular, to a system and a method for monitoring a state of a power electronic device using an electromagnetic voiceprint.

### BACKGROUND

A power electronic device plays an important role in new energy power generation, special equipment, rail transportation and other fields, and are the key to achieving power conversion. Since the power electronic device often works in turn-on and turn-off states and are frequently subjected to high voltage and high current shocks, the power electronic device is easily affected by repeated thermal and mechanical stresses, which in turn causes fatigue damage and affects the normal operation of the device, posing a serious threat to a safe and stable operation of a system.

A current electrical parameter monitoring method for damage state monitoring of the power electronic device require changes to a working circuit of the power electronic device, and cannot achieve non-invasive monitoring and cannot detect early aging. An infrared thermal parameter monitoring method has a high monitoring equipment cost and requires removing a packaging of the device. An aging model-based monitoring method has problems of poor accuracy and low reliability due to inability to accurately model for the aging. Currently, there is no method with non-invasive, highly sensitive, and ability of detecting early aging defects for monitoring the state of power electronic device.

### SUMMARY

A first aspect of embodiments of the present disclosure proposes a system for monitoring a state of a power electronic device using an electromagnetic voiceprint. The system includes an electromagnetic voiceprint acquisition apparatus and a system main control module.

The electromagnetic voiceprint acquisition apparatus includes a resonant piezoelectric velocity sensor, a voiceprint signal acquisition module, a self-powered power supply module and a first wireless communication module.

The system main control module includes a second wireless communication module, a central processor, a voiceprint storage unit, a voiceprint display unit and an aging assessment module, where the second wireless communication module is in communication connection to the first wireless communication module.

A second aspect of embodiments of the present disclosure provides a method for monitoring a state of a power electronic device using an electromagnetic voiceprint. The method is applied to the above-mentioned system for monitoring a state of a power electronic device using an electromagnetic voiceprint. The method includes:
acquiring electromagnetic voiceprint signals of the power electronic device with a vibration direction perpendicular to a resonant piezoelectric velocity sensor during a turn-on transient and a turn-off transient, wherein the electromagnetic voiceprint signals are acquired by removing interference data caused by a transient electromagnetic coupling noise in space during the acquisition via a preamplifier and a filtering circuit;
obtaining an electromagnetic voiceprint signal time sequence by performing data enhancement on the acquired electromagnetic voiceprint signals;
calculating an electromagnetic voiceprint energy time sequence and an electromagnetic voiceprint cumulative energy time sequence based on the electromagnetic voiceprint signal time sequence; and
assessing an aging state and a remaining lifetime of the power electronic device in real time by comparing the electromagnetic voiceprint cumulative energy time sequence with a historical electromagnetic voiceprint cumulative energy time sequence and comparing against a lifetime fitting curve obtained through a power cycling accelerated aging test.

Additional aspects and advantages of the present disclosure will be given in part in the description below, and in part will become apparent from the description below, or will be learned through practice of the present disclosure.

### BRIEF DESCRIPTION OF THE DRAWINGS

The above and/or additional aspects and advantages of the present disclosure will become apparent and easily understood from the following description of the embodiments in combination with the accompanying drawings.

FIG. 1 is a schematic structural diagram of a system for monitoring a state of a power electronic device using an electromagnetic voiceprint provided by an embodiment of the present disclosure.

FIG. 2 is a flow chart of a method for monitoring a state of a power electronic device using an electromagnetic voiceprint provided by an embodiment of the present disclosure.

FIG. 3 is a schematic diagram of a time domain waveform of an electromagnetic voiceprint signal of a power electronic device according to an embodiment of the present disclosure.

FIG. 4 is a schematic diagram of an electromagnetic voiceprint accumulated energy time sequence of power electronic devices at different aging states according to an embodiment of the present disclosure.

### DETAILED DESCRIPTION

Embodiments of the present disclosure are described in detail below, examples of which are shown in the accompanying drawings, where the same or similar reference numerals represent the same or similar elements or elements with the same or similar functions. The embodiments described below with reference to the accompanying drawings are examples and are intended to be used to explain the present disclosure, but should not be understood as limiting the present disclosure.

The following describes a system and a method for monitoring a state of a power electronic device using an electromagnetic voiceprint according to the embodiments of the present disclosure with reference to the accompanying drawings.

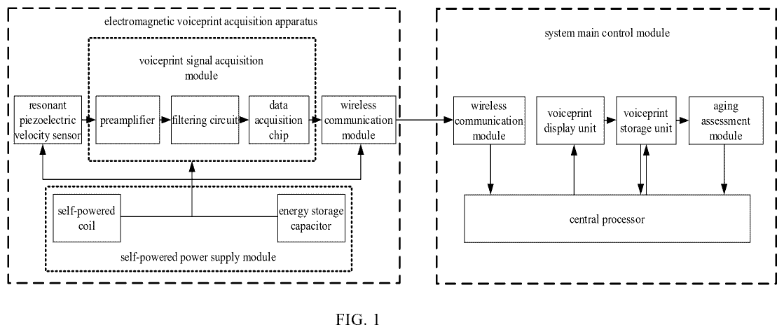

FIG. 1 is a schematic structural diagram of a system for monitoring a state of a power electronic device using an electromagnetic voiceprint provided by an embodiment of the present disclosure.

As shown in FIG. 1, the system for monitoring the state of the power electronic device using the electromagnetic voiceprint includes an electromagnetic voiceprint acquisition apparatus and a system main control module.

The electromagnetic voiceprint acquisition apparatus includes a resonant piezoelectric velocity sensor, a voiceprint signal acquisition module, a self-powered power supply module and a first wireless communication module.

In an embodiment, the electromagnetic voiceprint acquisition apparatus is arranged near a packaging housing or a heat sink of the power electronic device, and the resonant piezoelectric velocity sensor is coupled to the packaging housing or the heat sink of the power electronic device via a clamp or an adhesive.

In an embodiment, the resonant piezoelectric velocity sensor is installed at a selected position that is as close to a semiconductor chip as possible. When selecting, the position close to the semiconductor chip on the housing or the heat sink of the device is selected based on the structure of the power electronic device, so that acoustic impedance of a solid medium in a propagation path of the voiceprint signal from the inside of the device to the sensor is as small as possible.

In an embodiment, a resonant frequency of the resonant piezoelectric velocity sensor is 80 kHz to 150 kHz, and a peak sensitivity of the resonant piezoelectric velocity sensor is not less than 65 dB.

In an embodiment, a preamplifier and a filtering circuit are connected to the resonant piezoelectric velocity sensor, and filter out a transient electromagnetic noise and other electromagnetic interference noise. A sampling rate of the data acquisition chip is not less than 10 MHz, and a time length of an electromagnetic voiceprint signal extracted from a single turning on or turning off of the power electronic device is greater than 150 us.

In an embodiment, the power supply module supplies power using a combination of a self-powered coil and an energy storage capacitor. The self-powered coil is installed on a collector pin of the power electronic device and obtains energy through the electromagnetic induction principle. The energy storage capacitor is configured to store the obtained energy and drive the electromagnetic voiceprint acquisition apparatus to complete a signal acquisition and a wireless transmission.

In an implementation, the data acquisition processor adopts the STM32F7 series high-performance single-chip microcomputer produced by STMicroelectronics; and the electromagnetic voiceprint monitoring sensor adopts a piezoelectric sensor with a resonant frequency of 150 kHz and a peak sensitivity of 75 dB.

The system main control module includes a second wireless communication module, a central processor, a voiceprint storage unit, a voiceprint display unit and an aging assessment module. The second wireless communication module is communicatively connected to the first wireless communication module.

In an embodiment, the central processor receives voiceprint information transmitted by the wireless communication module, displays a waveform of the voiceprint information in the voiceprint display unit, and stores the voiceprint information in the voiceprint storage unit. The central processor also receives the assessment result of the aging evaluation module and marks the assessment result in the voiceprint display unit.

In an embodiment, the aging assessment module extracts historical voiceprint data from the voiceprint storage unit, performs feature extraction and time sequence feature analysis on the voiceprint signal, assesses a current aging state of the power electronic device, and predicts a lifetime of the device.

In an implementation, the wireless communication module adopts a Wi-Fi networking communication mode, and is used for mutual communication between the system's multiple electromagnetic voiceprint signal acquiring apparatuses and the system's main control module.

The system for monitoring the state of the power electronic device using the electromagnetic voiceprint of the embodiment of the present disclosure implements the aging state monitoring based on the electromagnetic voiceprint signals of the turn-on transient and turn-off transient of the power electronic device. The system can monitor and assess the aging state of the device in real time and predict the remaining lifetime, with higher monitoring sensitivity and higher reliability; the method solving model is simple and has good real-time performance; and the system power consumption is low.

In order to implement the above embodiment, the present disclosure also proposes a method for monitoring a state of a power electronic device using an electromagnetic voiceprint. The method is applicable to the above-mentioned system for monitoring the state of the power electronic device using the electromagnetic voiceprint.

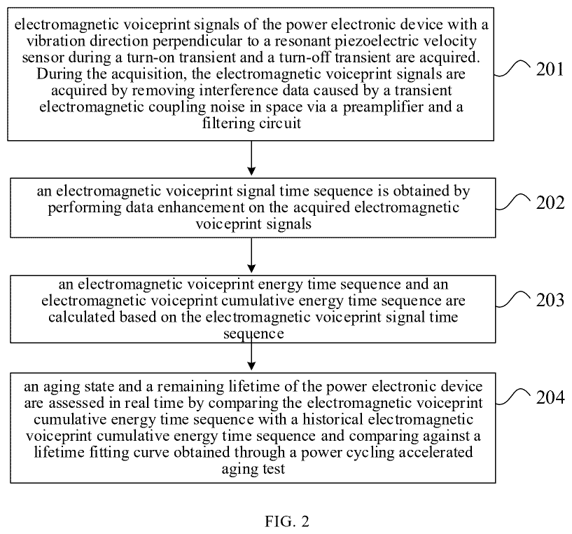

FIG. 2 is a flow chart of a method for monitoring a state of a power electronic device using an electromagnetic voiceprint provided by an embodiment of the present disclosure.

As shown in FIG. 2, the method for monitoring the electromagnetic voiceprint of a power electronic device includes the following steps.

Step 201, electromagnetic voiceprint signals of the power electronic device with a vibration direction perpendicular to a resonant piezoelectric velocity sensor during a turn-on transient and a turn-off transient are acquired. During the acquisition, the electromagnetic voiceprint signals are acquired by removing interference data caused by a transient electromagnetic coupling noise in space via a preamplifier and a filtering circuit.

In an embodiment, removing the interference data caused by the transient electromagnetic coupling noise in the space via the preamplifier and the filtering circuit includes: determining a signal frequency band greater than 1 MHz as a noise caused by electromagnetic coupling to a sensor during the turn-on transient and turn-off transient of the power electronic device.

Step 202, an electromagnetic voiceprint signal time sequence is obtained by performing data enhancement on the acquired electromagnetic voiceprint signals.

In an embodiment, the central processor assesses the signal quality and performs data enhancement to obtain the electromagnetic voiceprint signal time sequence. The data enhancement includes but is not limited to: cubic spline interpolation of voiceprint signals, subsequence feature enhancement based on voiceprint signal decomposition, and data repair based on a historical voiceprint statistical rule.

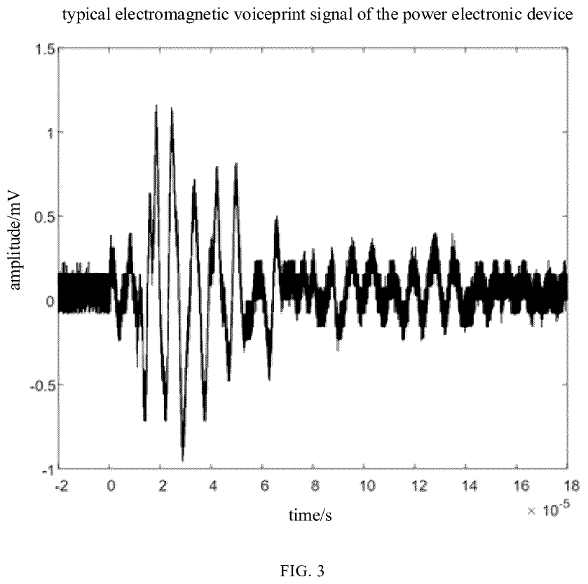

For example, a waveform of the acquired electromagnetic voiceprint signal is shown in FIG. 3. The filtering circuit uses low-pass filtering with a cutoff frequency of 1 MHz. The cubic spline interpolation is used for waveform repair, and a final waveform length is 180 us and a sampling rate is 100 MHz.

Step 203, an electromagnetic voiceprint energy time sequence and an electromagnetic voiceprint cumulative energy time sequence are calculated based on the electromagnetic voiceprint signal time sequence.

In an embodiment, the electromagnetic voiceprint energy time sequence E(t), the electromagnetic voiceprint cumulative energy time sequence S(t), and the electromagnetic voiceprint signal time sequence X(t) satisfy the following relationship:

$$S ( {t}_{0} ) = {\sum }_{t = 0}^{{t}_{0}} E ( t ) = {\sum }_{t = 0}^{{t}_{0}} {X}^{2} ( t )$$

Step 204, an aging state and a remaining lifetime of the power electronic device are assessed in real time by comparing the electromagnetic voiceprint cumulative energy time sequence with a historical electromagnetic voiceprint cumulative energy time sequence and comparing against a lifetime fitting curve obtained through a power cycling accelerated aging test.

In an embodiment, the lifetime fitting curve obtained by the power cycling accelerated aging test includes: a group of electromagnetic voiceprint cumulative energy curves from being intact to failure of the power electronic device, a separation time point, and a power cycling number curve.

In an embodiment, the electromagnetic voiceprint cumulative energy time sequence is compared with the historical electromagnetic voiceprint cumulative energy time sequence, the sequence separation time point and the sequence maximum value are analyzed, and the electromagnetic voiceprint cumulative energy time sequence is compared against the lifetime fitting curve obtained through the power cycling accelerated aging test, so as to assess the aging state and the remaining lifetime of the power electronic device in real time.

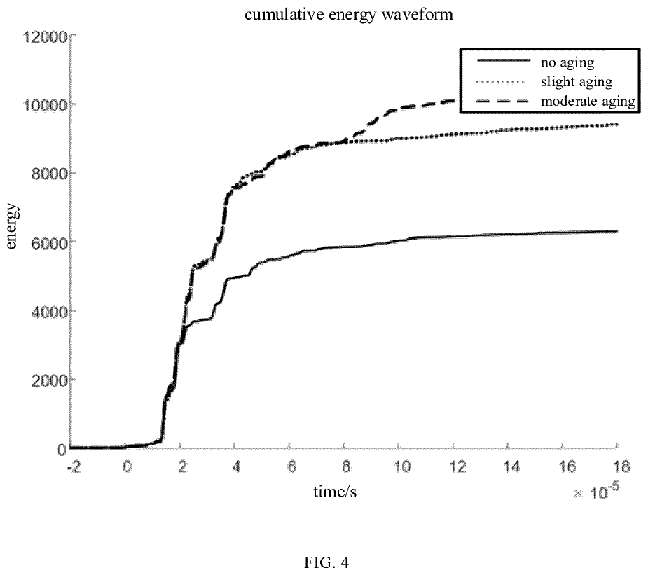

For example, the electromagnetic voiceprint cumulative energy time sequence is shown in FIG. 4. The lifetime fitting curve obtained from the power cycling accelerated aging test is used to assess the aging state of the device, and an assessment result of no aging, slight aging, or moderate aging are obtained.

The method for monitoring the state of the power electronic device using the electromagnetic voiceprint of the embodiment of the present disclosure can use the electromagnetic voiceprint signal emitted by the power electronic device switching transient to monitor the device aging state and assess the remaining lifetime at the same time. The method solving model is simple, with fast judgment speed and good real-time performance.

It should be noted that the above explanation of the embodiment of the system for monitoring the state of the power electronic device using the electromagnetic voiceprint is also applicable to the method for monitoring the state of the power electronic device using the electromagnetic voiceprint of this embodiment, and will not be repeated here.

In the description of the present disclosure, the term, such as “an embodiment”, “some embodiments”, “example”, “specific example” or “some examples”, means that the specific features, structures, materials or characteristics described in combination with the embodiment or example are included in at least an embodiment or example of the present disclosure. In the description, the schematic expressions of the above terms do not necessarily refer to the same embodiment or example. Furthermore, the specific features, structures, materials, or characteristics described may be combined in any suitable manner in any one or more embodiments or examples. Furthermore, those skilled in the art may combine different embodiments or examples and features of different embodiments or examples described in the present disclosure without mutual contradiction.

In addition, the terms “first”, “second”, etc., are used for descriptive purposes only and should not be understood as indicating or implying relative importance or implicitly indicating the quantity of the indicated technical features. Therefore, features defined with “first” or “second” may explicitly or implicitly include at least one of the features. In the description of the present disclosure, “a plurality of” means at least two, for example, two, three, etc., unless otherwise clearly defined.

Any process or method description in a flowchart or otherwise described herein may be understood to represent a module, segment or portion of code including one or more executable instructions for implementing the steps of a custom logical function or process, and the scope of the preferred embodiments of the present disclosure includes alternative implementations in which functions may be performed out of the order shown or discussed, including performing functions in a substantially simultaneous manner or in the reverse order depending on the functions involved, which should be understood by those skilled in the art to which the embodiments of the present disclosure belong.

The logic and/or steps represented in the flowchart or otherwise described herein may be considered, for example, as an ordered list of executable instructions for implementing logical functions, and may be embodied in any computer-readable medium for use by, or in conjunction with, an instruction execution system, apparatus, or device (such as a computer-based system, a system including a processor, or other system that can execute instructions obtained from an instruction execution system, apparatus, or device). For the purposes of the present disclosure, a “computer-readable medium” can be any apparatus that may contain, store, communicate, propagate, or transport a program for use by an instruction execution system, apparatus, or device, or in connection with such instruction execution system, apparatus, or device. More specific examples (a non-exhaustive list) of the computer-readable medium include: an electrical connection having one or more wires (electronic device), a portable computer disk cartridge (magnetic device), random access memory (RAM), read-only memory (ROM), erasable and programmable read-only memory (EPROM or flash memory), fiber optic device, and a portable compact disc read-only memory (CDROM). Furthermore, the computer-readable medium may even be paper or other suitable medium on which the program is printed, since the program may be obtained electronically, for example, by optically scanning the paper or other medium and then editing, interpreting or processing it in another suitable manner if necessary, and then storing it in a computer memory.

It should be understood that various parts of the present disclosure can be implemented by hardware, software, firmware or a combination thereof. In the above embodiments, multiple steps or methods may be implemented by software or firmware stored in a memory and executed by a suitable instruction execution system. For example, if implemented in hardware, as in another embodiment, it can be implemented using any one of the following technologies known in the art or a combination thereof: a discrete logic circuit having a logic gate circuit for implementing logical functions on data signals, a dedicated integrated circuit having a suitable combination of logic gate circuits, a programmable gate array (PGA), a field programmable gate array (FPGA), etc.

Those skilled in the art will understand that all or part of the steps in the methods of the above embodiments can be completed by instructing related hardware through a program, and the program can be stored in a computer-readable storage medium. When the program is executed, it includes one or a combination of the steps of the method embodiments.

In addition, each functional unit in each embodiment of the present disclosure may be integrated into one processing module, or each unit may exist physically separately, or two or more units may be integrated into one module. The above integrated modules can be implemented in the form of hardware or software functional modules. If the integrated module is implemented in the form of a software function module and sold or used as an independent product, it can also be stored in a computer-readable storage medium.

The storage medium mentioned above can be a read-only memory, a magnetic disk or an optical disk, etc. Although the embodiments of the present disclosure have been shown and described above, it can be understood that the above embodiments are exemplary and cannot be understood as limitations on the present disclosure. A person skilled in the art can change, modify, replace and modify the above embodiments within the scope of the present disclosure.

What is claimed is:

1. A system for monitoring a state of a power electronic device using an electromagnetic voiceprint, comprising an electromagnetic voiceprint acquisition apparatus and a system main control module, wherein:
the electromagnetic voiceprint acquisition apparatus comprises a resonant piezoelectric velocity sensor, a voiceprint signal acquisition module, a self-powered power supply module and a first wireless communication module; and
the system main control module comprises a second wireless communication module, a central processor, a voiceprint storage unit, a voiceprint display unit and an aging assessment module, wherein the second wireless communication module is in communication connection to the first wireless communication module.

2. The system according to claim 1, wherein the electromagnetic voiceprint acquisition apparatus is arranged on a packaging housing or a heat sink of the power electronic device, the resonant piezoelectric velocity sensor is coupled to the packaging housing or the heat sink of the power electronic device via a clamp or an adhesive, and the resonant piezoelectric velocity sensor is installed at a selected position closest to a semiconductor chip.

3. The system according to claim 1, wherein the resonant piezoelectric velocity sensor has a resonant frequency of 80 kHz to 150 kHz and a peak sensitivity of not less than 65 dB.

4. The system according to claim 1, wherein the voiceprint signal acquisition module comprises a preamplifier, a filtering circuit and a data acquisition chip, the preamplifier is connected to the resonant piezoelectric velocity sensor, the data acquisition chip has a sampling rate of not less than 10 MHz, and a time length of an electromagnetic voiceprint signal extracted from a single turning on or turning off of the power electronic device is greater than 150 us.

5. The system according to claim 1, wherein the self-powered power supply module comprises a self-powered coil and an energy storage capacitor, the self-powered coil is installed on a collector pin of the power electronic device, the self-powered coil obtains energy through an electromagnetic induction principle, and the energy storage capacitor stores the energy obtained by the self-powered coil.

6. The system according to claim 1, wherein the central processor receives voiceprint information transmitted by the second wireless communication module, displays a waveform of the voiceprint information in the voiceprint display unit, and stores the voiceprint information in the voiceprint storage unit; the aging assessment module assesses an aging state of the power electronic device based on data stored in the voiceprint storage unit; and the central processor receives an assessment result of the aging assessment module and marks the assessment result in the voiceprint display unit.

7. A method for monitoring a state of a power electronic device using an electromagnetic voiceprint, applied to a system for monitoring the state of the power electronic device using the electromagnetic voiceprint, the method comprising:
acquiring electromagnetic voiceprint signals of the power electronic device with a vibration direction perpendicular to a resonant piezoelectric velocity sensor of the system during a turn-on transient and a turn-off transient, wherein the electromagnetic voiceprint signals are acquired by removing interference data caused by a transient electromagnetic coupling noise in space during acquisition via a preamplifier of the system and a filtering circuit of the system;
obtaining an electromagnetic voiceprint signal time sequence by performing data enhancement on the acquired electromagnetic voiceprint signals;
calculating an electromagnetic voiceprint energy time sequence and an electromagnetic voiceprint cumulative energy time sequence based on the electromagnetic voiceprint signal time sequence; and
assessing an aging state and a remaining lifetime of the power electronic device in real time by comparing the electromagnetic voiceprint cumulative energy time sequence with a historical electromagnetic voiceprint cumulative energy time sequence and comparing against a lifetime fitting curve obtained through a power cycling accelerated aging test.

8. The method according to claim 7, wherein removing the interference data caused by the transient electromagnetic coupling noise in the space via the preamplifier and the filtering circuit comprises:
determining a part of a signal frequency band greater than 1 MHz as a noise caused by electromagnetic coupling to the resonant piezoelectric velocity sensor during the turn-on transient and the turn-off transient of the power electronic device.

9. The method according to claim 7, wherein the data enhancement comprises at least one of cubic spline interpolation of a voiceprint signal, subsequence feature enhancement based on voiceprint signal decomposition, or data repair based on a historical voiceprint statistical rule; and the electromagnetic voiceprint cumulative energy time sequence is expressed as:
$$S ( {t}_{0} ) = {\sum }_{t = 0}^{{t}_{0}} E ( t ) = {\sum }_{t = 0}^{{t}_{0}} {X}^{2} ( t )$$
where S(t) is the electromagnetic voiceprint cumulative energy time sequence, X(t) is the electromagnetic voiceprint signal time sequence, and E(t) is the electromagnetic voiceprint energy time sequence.

10. The method according to claim 7, wherein the lifetime fitting curve obtained by the power cycling accelerated aging test comprises: a group of electromagnetic voiceprint cumulative energy curves from being intact to failure of the power electronic device, a separation time point, and a power cycling number curve.
